(19) United States
(12) Patent Application Publication
(10) Pub. No.: US 2026/0023913 A1
(43) Pub. Date: Jan. 22, 2026

(54) AREA-EFFICIENT FUNCTIONAL SAFETY IN COMPUTER PROCESSING UNITS

(71) Applicant: Tenstorrent USA, Inc., Austin, TX (US)

(72) Inventor: Aniket Mukul Saha, Austin, TX (US)

(21) Appl. No.: 18/778,311

(22) Filed: Jul. 19, 2024

(51) Int. Cl. G06F 30/398; G06F 1/06

(52) U.S. Cl. CPC G06F 30/398; G06F 1/06

(57) ABSTRACT

Systems and methods related to area-efficient functional safety are disclosed. A main core may have a first physical design and register transfer level (RTL) description. A secondary core may have a second physical design. The secondary core may have the same RTL description, but the first physical design may focus on performance and speed while the second physical design focuses on area-efficiency or low power. The secondary core may have a portion of the same RTL, but a different RTL description overall. The portion that is described by the same RTL may be an error prone portion of the main core. In either case, the secondary core may be physically smaller than the main core. The secondary core may be used to monitor for errors of the main core during operation. The main core may slow down when the main core and secondary core are operated in lockstep.

### BACKGROUND

Industry specifications indicate requirements for functional safety. For example, the Automotive safety Integral Level (ASIL) International Standard for Organization (ISO) 26262, indicates requirements for functional safety for road vehicles, and specifically electrical and/or electronic systems that are installed in most serial production road vehicles. ASIL is further categorized into different standards such as ASIL A, ASIL B, ASIL C, and ASIL D. To decrease the risk of an error or failure, a computation may be run on two different processor cores in lockstep, with one core checking the work of the other core to search for errors. Lockstep systems run an operation on two or more processors in parallel. Sometimes the operations are performed at the same time across the processors. Sometimes there is a delay (timeshift) between processors to increase the probability of detecting errors induced by external influences such as voltage spikes and ionizing radiation. The outputs from the two or more processors are compared to detect errors. If the outputs are different, then an error may have occurred in one of the processors. If the outputs match, then the absence of an error may be assumed. To run in lockstep, each processor progresses from one well-defined state to the next well-defined state. For example, the changes of: new inputs, new outputs, and a state update, defines a step between the well-defined states. ASIL standards require lockstep systems for certain electronic systems are installed in most serial production road vehicles.

### SUMMARY

This disclosure relates to area-efficient functional safety in computer processing units (CPUs). A network of processor units (e.g., cores) may be designed such that there are different physical designs for different processor units. A main core may have a first physical design or register transfer level (RTL) description. A secondary core (or shadow core) may have a second physical design or a second RTL description. In specific embodiments, the main core and the secondary core will have the same RTL description, but the main core will have a physical design that focuses on t performance and speed and the secondary core will have a different physical design that focuses on efficient use of area. The secondary core may be physically smaller than the main core. The secondary core may also be slower than the main core. The secondary core may refrain from performing all the processes that the main core performs, and may simulate processing done by portions of the main core. The secondary core may be used to monitor for errors of the main core during operation.

The main core and the secondary core may operate in lock step. The main core and the secondary core may operate in lock step to support functional safety requirements. In specific embodiments, the main core may slow down (e.g., use a lower clock frequency) to match the capability of the secondary core when the cores operate in lock step. In specific embodiments, the secondary core may be designed to include portions of the main core that are more prone to errors. Which portions of the main core are prone to errors may be determined via an iterative process. When the secondary core refrains from, or is not capable of performing, a process that the main core performs, the secondary core may simulate the result of that process from the main core.

In specific embodiments of the invention, a network of processor cores is provided. The network of processor cores comprises: a first processor core associated with a first physical design and having a portion of the first processor core defined by a register transfer level (RTL) description; a second processor core connected with the first processor core, the second processor core being associated with a second physical design and having a portion of the second processor core defined by the RTL description. The second physical design uses a smaller area than the first physical design. The network of processor cores further comprises at least one non-transitory computer-readable medium storing instructions that: (i) cause the first processor core and the second processor core to execute a test computation using the portion of the first processor core and the portion of the second processor core; and (ii) cause a result of the test computation from the first processor core and a result of the test computation from the second processor core to be available for a functional safety analysis.

In specific embodiments of the invention, a method for conducting a functional safety analysis using a network of processor cores is provided. The method comprises executing, by a portion of a first processor core, a test computation. The first processor core is associated with a first physical design and the portion of the first processor core is defined by a RTL description. The method also comprises executing, by a portion of a second processor core, the test computation. The second processor core operates in connection with the first processor core, is associated with a second physical design that uses a smaller area than the first physical design, and the portion of the second processor core is defined by the RTL description. The method also comprises providing a first result of the execution by the portion of the first processor core for the functional safety analysis, and providing a second result of the execution by the portion of the second processor core for the functional safety analysis.

In specific embodiments of the invention, a method of designing a network of processor cores is provided. The method of designing a network of processor cores comprises checking a design of a first processor core for one or more first error-prone portions, the one or more first error-prone portions having one or more error-prone designs, compiling a second processor core that includes one or more second error-prone portions having the one or more error-prone designs and that has a different physical design than the first processor core, executing, by the one or more first error-prone portions of the first processor core, a test computation, and executing, by the one or more second error-prone portions of the second processor core, the test computation. The second processor core operates in connection with the first processor core. The method also comprises providing a first result of the execution by the one or more first error-prone portions of the first processor core for a functional safety analysis, and providing a second result of the execution by the one or more second error-prone portions of the second processor core for the functional safety analysis.

### BRIEF DESCRIPTION OF THE DRAWINGS

The accompanying drawings illustrate various systems, methods, and other aspects of the disclosure. A person with ordinary skills in the art will appreciate that the illustrated element boundaries (e.g., boxes, groups of boxes, or other shapes) in the figures represent one example of the boundaries. It may be that in some examples one element may be designed as multiple elements or that multiple elements may be designed as one element. In some examples, an element shown as an internal component of one element may be implemented as an external component in another, and vice versa. Furthermore, elements may not be drawn to scale. Non-limiting and non-exhaustive descriptions are described with reference to the following drawings. The components in the figures are not necessarily to scale, emphasis instead being placed upon illustrating principles.

FIG. 1 provides a main processor core and a shadow processor core in accordance with specific embodiments of the inventions disclosed herein.

FIG. 2 provides a main processor core and a shadow processor core where a portion of the shadow processor core simulates a portion of the main processor core in accordance with specific embodiments of the inventions disclosed herein.

FIG. 3 provides a network of processor cores in accordance with specific embodiments of the inventions disclosed herein.

FIG. 4 provides a timing diagram for a network with a smaller shadow processor core in accordance with specific embodiments of the inventions disclosed herein.

FIG. 5 provides a timing diagram for a network with a shadow core having a simulated portion of a main processor core in accordance with specific embodiments of the inventions disclosed herein.

FIG. 6 provides a method for performing a functional safety analysis in accordance with specific embodiments of the inventions disclosed herein.

FIG. 7 provides a method for performing a functional safety analysis with a reduced clock frequency in a main processor core in accordance with specific embodiments of the inventions disclosed herein.

FIG. 8 provides a method for performing a functional safety analysis in accordance with specific embodiments of the inventions disclosed herein.

### DETAILED DESCRIPTION

Reference will now be made in detail to implementations and embodiments of various aspects and variations of systems and methods described herein. Although several exemplary variations of the systems and methods are described herein, other variations of the systems and methods may include aspects of the systems and methods described herein combined in any suitable manner having combinations of all or some of the aspects described.

Different systems and methods for area-efficient functional safety in computer processing units in accordance with the summary above are described in detail in this disclosure. The methods and systems disclosed in this section are nonlimiting embodiments of the invention, are provided for explanatory purposes only, and should not be used to constrict the full scope of the invention. It is to be understood that the disclosed embodiments may or may not overlap with each other. Thus, part of one embodiment, or specific embodiments thereof, may or may not fall within the ambit of another, or specific embodiments thereof, and vice versa. Different embodiments from different aspects may be combined or practiced separately. Many different combinations and sub-combinations of the representative embodiments shown within the broad framework of this invention, that may be apparent to those skilled in the art but not explicitly shown or described, should not be construed as precluded.

A main core (e.g., main processor core) and a shadow core (e.g., shadow processor core) may be part of a fault-tolerant computer system. The cores may be part of a fault-tolerant computer system in which the shadow core checks the result of at least one computation or operation of the main core. The shadow core may be used in hard-lock step as a checker core for the main core. The shadow core may be physically smaller than the main core. In specific embodiments, the main core may use high performance design options. For example, the main core may incorporate tall library cells, an aggressive use of ultra-low threshold voltage (e.g., Vt) cells, high performance margin methodology, non-default routing rules, high performance standard cells, and other options which enable a high maximum clock frequency (e.g., Fmax) design. Tall library cells (e.g., high-speed library cells) may allow for peak performance for critical paths. Non-default routing rules may reduce interconnect latency for both signal and clock. High performance standard cells may allow for faster switching times.

The main core may incorporate many features such as high speed flip-flop (FF), area optimized FF, multi-bit flip-flop (MBFF, e.g., of 2, 4, or 8 bits), special clock drivers, integrated clock gates, delay cells, being metastable optimized, complex combinations, high performance sequential logic circuits, data path arithmetic circuits, fast cache instances, clock routing network detection and routing (NDR) circuitry, signal routing NDR circuity, high speed vias, default NDR, advanced on chip variation (AOCV) derate circuitry, threshold voltage cell mixes of more than 10% ultra-low-voltage transistors (ULVT), supply voltage (VDD) use, coarse grained power gating, clock gating, and clock uncertainty circuitry.

In specific embodiments, the shadow core may use power-efficient design options or area-efficient design options. The shadow core may incorporate features such as area optimized FF, MBFF (e.g., 2, 4, or 8 bits), integrated clock gates, delay cells, metastable optimized, low dynamic power FF, ultra-high-density elements, high density single power elements such as high-density or ultra-high-density single port or multi-port RAMS, default NDR, standard AOCV derates, few or zero ULVT cells in the threshold voltage cell mix, fine grained power gating, and clock gating. The maximum clock frequency (e.g., Fmax) of the shadow core may be at the low or mid end of the frequency range of the main core. The main core and the shadow core may operate at the same frequency when the cores are in locked mode.

In specific embodiments, the shadow core may operate more slowly than the main core. The shadow core may refrain from performing (e.g., executing) every operation that the main core performs. The main core may operate at a first clock frequency when performing a first set of (e.g., one or more) operations, for example operations that the shadow core refrains from performing and when the devices are not operating in lockstep. The main core may operate at a second clock frequency when performing a second set of (e.g., one or more) operations, for example operations that the shadow core performs and when the devices are operating in lockstep. The shadow core may perform at the second clock frequency when performing operations. The first clock frequency may be higher than the second clock frequency. In other words, the main core may perform operations at a high speed (e.g., first clock frequency, higher clock frequency). The shadow core may not be capable of operating at the high speed and may instead operate at a low speed (e.g., second clock frequency, lower clock frequency). When the shadow core is used to check the operation of the main core, the main core may slow down (e.g., from the high speed to the low speed) to match the shadow core during the execution of the operation conducted while the cores are operating in lockstep. For example, the main core slows from the first clock frequency to the second clock frequency.

In specific embodiments, the shadow core may be designed with configurations which reduce its area even more without impacting its functionality. For example, the main core may have larger caches and buffer sizes compared to the shadow core to enable high single thread performance of the main core while the shadow core may smaller caches and reduced buffer structures enabled to match the functionality of the main core while also reducing the physical area of the shadow core. The shadow core may also be designed without external interfaces and ports (e.g., those associated with input/output (IO) coherence). Removing, or refraining from including, the external interfaces and ports may change the functionality of the shadow core and reduce the physical size of the shadow core.

In specific embodiments, the main core may be analyzed to identify which portions of the main core are more susceptible to faults (e.g., are error-prone). The shadow core may be designed to duplicate those portions of the main core such as at the RTL level. The shadow core may be designed to simulate other portions of the main core. As such, the functionality of the shadow core may be more limited than the main core thereby reducing the physical size of the shadow core relative to the main core in this manner.

Accordingly, at the register transfer level (RTL), the shadow core and the main core may be different. However, even if the shadow core and the main core are identical at the RTL level, the shadow core may have a different power, performance, and area (PPA) compared to the main core. Additionally, the shadow core and the main core may have both different RTL and the portions of RTL they share in common may be physically instantiated in different ways to further reduce the relative size of the shadow core. For example, the shadow core may have less area compared to the main core, and the functional differences between the main core and the shadow core further reduce the area of the shadow core. The main core and shadow core may not need a temporal separation or delay when operating together for error checking, as transient faults may not affect both cores in the same way due to the differing designs.

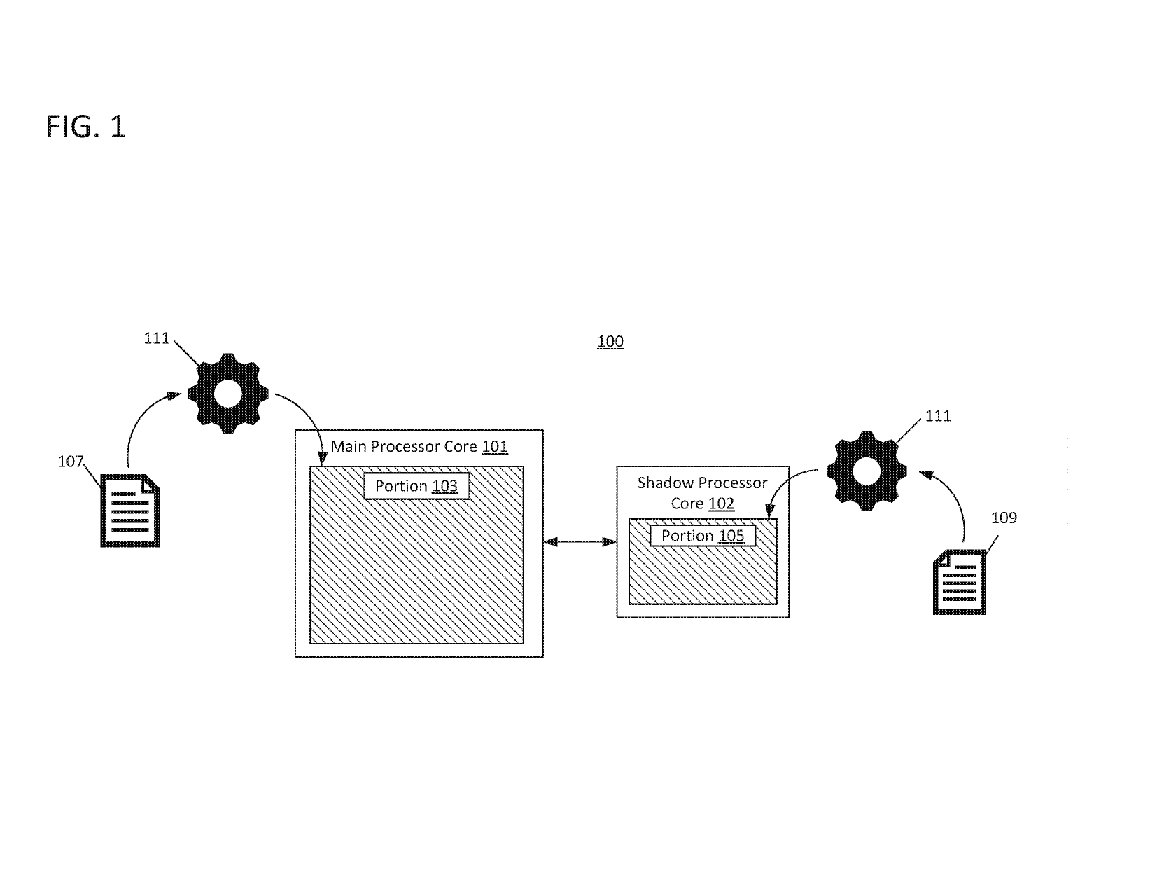

FIG. 1 illustrates main processor core 101 and shadow processor core 102 as part of network 100 in accordance with specific embodiments of the inventions disclosed herein. Main processor core 101 (also called a primary processor core) may include portion 103. Shadow processor core 102 (also called a secondary processor core) may include portion 105. Main processor core 101 and shadow processor core 102 may be connected in the network and may operate in lockstep. Instructions associated with main processor core 101 and shadow processor core 102 may be stored in at least one non-transitory computer-readable medium.

Main processor core 101 may have a first physical design. The first physical design may refer to the space that the main processor core 101 occupies, the types of components that make up the main processor core 101, and the layout of these components. Portion 103 may be associated with (e.g., correspond to, be defined by) register transfer level (RTL) description 107. RTL description 107 may be compiled by compiler 111 to create portion 103. Shadow processor core 102 may have a second physical design. The second physical design may refer to the space that the shadow processor core 102 occupies, the types of components that make up the shadow processor core 102, and the layout of these components. Portion 105 may be associated with (e.g., correspond to, be defined by) RTL description 109. RTL description 109 may be compiled by compiler 111 to create portion 105.

In specific embodiments, main processor core 101 and shadow processor core 102 may each execute a computation (e.g., a test computation). The result of the execution by main processor core 101 and shadow processor core 102 may be available for functional safety analysis. Main processor core 101 may execute the computation using portion 103. Shadow processor core 102 may execute the computation using portion 105. In specific embodiments the test computation may be part of the regular workload of the main processor core 101, but it can be considered a test computation because shadow processor core 102 executes the computation at the same time.

In specific embodiments, RTL description 107 and RTL description 109 may be the same RTL description. Shadow processor core 102 may be physically smaller than main processor core 101 due to the physical implementation of RTL description 109. For example, the physical design (e.g., the first physical design) of main processor core 101 may use higher speed physical cells than are used for the physical design (e.g., the second physical design) of shadow processor core 102. Accordingly, main processor core 101 and shadow processor core 102 may be functionally identical cores but be designed with different physical areas.

In specific embodiments, main processor core 101 may use high performance design options. For example, main processor core 101 may use tall library cells, an aggressive use of ultra-low threshold voltage (e.g., Vt) cells, high performance margin methodology, non-default routing rules, high performance standard cells, and other options which enable a high maximum clock frequency (e.g., Fmax) design.

In specific embodiments, shadow processor core 102 may use power-efficient or area-efficient design options. The maximum clock frequency (e.g., Fmax) of shadow processor core 102 may be at the low or mid end of the frequency range of the main processor core 101. Network 100 may enable main processor core 101 and shadow processor core 102 to operate at the same frequency when the cores are in locked mode.

In specific embodiments, shadow processor core 102 may operate more slowly than main processor core 101. Shadow processor core 102 may refrain from performing (e.g., executing) every operation that main processor core 101 performs. Main processor core 101 may operate at a first clock frequency when performing a first set of (e.g., one or more) operations, for example operations that shadow processor core 102 refrains from performing and when the two cores are not operating in lock step. Main processor core 101 may operate at a second clock frequency when performing a second set of operations, for example operations that shadow processor core 102 performs and when the two cores are operating in lock step. Shadow processor core 102 may perform at the second clock frequency when performing operations. The first clock frequency may be higher than the second clock frequency. In other words, main processor core 101 may perform at a high speed (e.g., first clock frequency, higher clock frequency). Shadow processor core 102 may not be capable of operating at the high speed and may instead operate at a low speed (e.g., second clock frequency, lower clock frequency). When shadow processor core 102 is used to check an operation of main processor core 101, main processor core 101 may slow down (e.g., from the high speed to the low speed) to match shadow processor core when performing the operation. For example, main processor core 101 slows from the first clock frequency to the second clock frequency during the execution of the operation. The operation can be part of a computation conducted while the processors are operating in lockstep and the main processor may operate at the second clock frequency throughout the execution of the computation.

By using a lower clock frequency than main processor core 101, shadow processor core 102 may incorporate area-efficient components, use an area-efficient design, or both to result in a smaller physical area than main processor core 101. Due to the smaller physical area of shadow processor core 102, network 100 is cost-efficient while maintaining reduced errors and adhering to safety standards (e.g., ASIL ISO 26262).

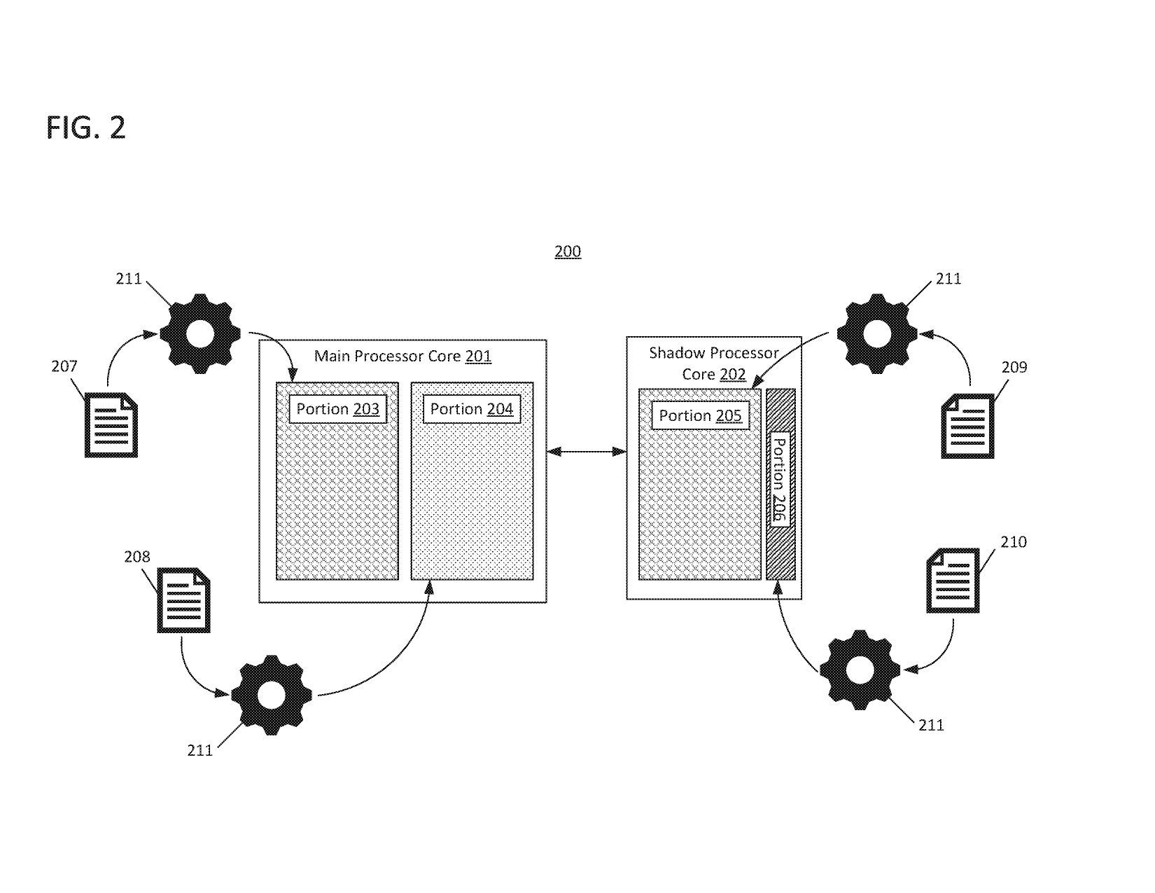

FIG. 2 illustrates main processor core 201 and shadow processor core 202 of network 200, in which a portion (e.g., portion 206) of shadow processor core 202 simulates a portion (e.g., portion 204) of main processor core 201, in accordance with specific embodiments of the inventions disclosed herein. Network 200 may include features related to network 100. Main processor core 201 (also called a primary processor core) may include portion 203 and portion 204. Shadow processor core 202 (also called a secondary processor core) may include portion 205 and portion 206. Main processor core 201 and shadow processor core 202 may be connected in the network and may operate in lockstep. Instructions associated with main processor core 201 and shadow processor core 202 may be stored in at least one non-transitory computer-readable medium.

Main processor core 201 may have a first physical design. The first physical design may refer to the space that the main processor core 201 occupies, the types of components that make up the main processor core 201, and the layout of these components. Portion 203 may be associated with (e.g., correspond to, be defined by) register transfer level (RTL) description 207. Portion 204 may be associated with RTL description 208. RTL description 207 may be compiled by compiler 211 to create portion 203. RTL description 208 may be compiled by compiler 211 to create portion 204.

Shadow processor core 202 may have a second physical design. The second physical design may refer to the space that the shadow processor core 202 occupies, the types of components that make up the shadow processor core 202, and the layout of these components. Portion 205 may be associated with (e.g., correspond to, be defined by) RTL description 209. Portion 206 may be associated with RTL description 210. RTL description 209 may be compiled by compiler 211 to create portion 205. RTL description 210 may be compiled by compiler 211 to create portion 206.

In specific embodiments, main processor core 201 and shadow processor core 102 may each execute a computation (e.g., a test computation). The result of the execution by main processor core 201 and shadow processor core 102 may be available for functional safety analysis. Main processor core 201 may execute the computation using portion 203. Shadow processor core 102 may execute the computation using portion 205. The main processor core 201 and the shadow processor core 202 may execute the computation in lock step.

In specific embodiments, RTL description 207 and RTL description 209 may be the same RTL description, while RTL description 208 and RTL description 210 are different RTL descriptions. Shadow processor core 202 may be physically smaller than main processor core 201 due to the RTL description 210 requiring a smaller area than RTL description 208 of main processor core 201. For example, because RTL description 210 requires less functionality than RTL description 208. In these embodiments, portion 203 may be an error-prone portion of main processor core 201.

In specific embodiments, an iterative process may be used to determine which portions of a core are prone to failure. For example, during failure modes, effects, and diagnostic analysis (FMEDA), portions (e.g., areas) of main processor core 201 may be identified as being more susceptible to faults than other portions of main processor core 201. For example, in specific embodiments, it may be determined that portion 203 is an error-prone portion of main processor core 201.

In specific embodiments, shadow processor core 202 (e.g., portion 206) may simulate portions of main processor core 201 (e.g., portion 204). Shadow processor core 202 may refrain from performing (e.g., executing) every operation that main processor core 201 performs. Instead, shadow processor core 202 may simulate (e.g., using portion 206) reliable or less error-prone operations (e.g., associated with portion 204) of main processor core 201 and perform (e.g., using portion 205) error-prone operations (e.g., associated with portion 203).

Main processor core 201 may be representative of a set of main processor cores. For example, network 200 may include more than one main processor core with the first physical design. Shadow processor core 202 may be representative of a set of secondary processor cores. For example, network 200 may include more than one shadow processor core with the second physical design. The quantity of main processor cores in network 200 may be the same as, or different than, a quantity of shadow cores in network 200. Each shadow processor core 202 may be connected to (e.g., coupled with, connected via network) at least one main processor core 201.

By simulating some aspects of main processor core 201, shadow processor core 202 may incorporate area-efficient components, use an area-efficient design, or both to result in a smaller physical area than main processor core 201. Due to the smaller physical area of shadow processor core 202, network 200 is cost-efficient while maintaining reduced errors and adhering to safety standards (e.g., ASIL ISO 26262).

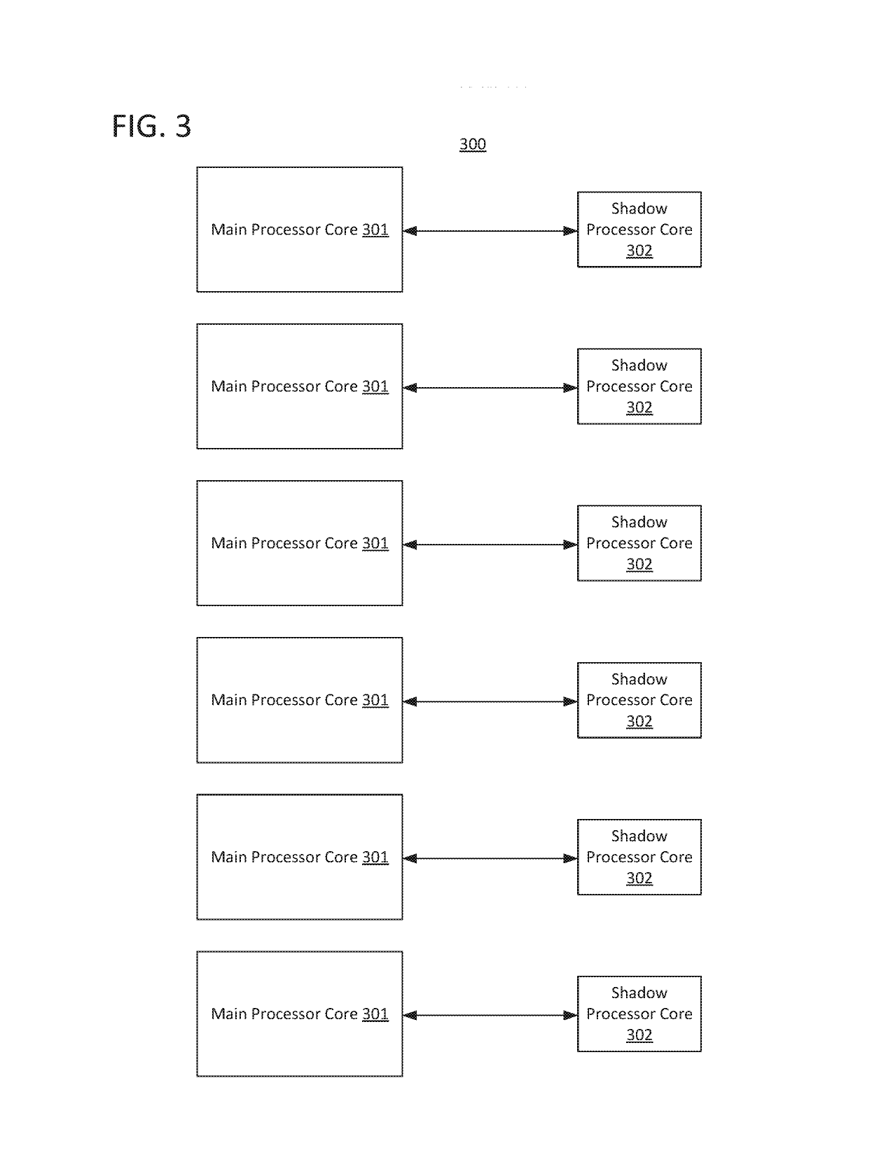

FIG. 3 illustrates network 300 of processor cores in accordance with specific embodiments of the inventions disclosed herein. Network 300 may include features of network 100, network 200, or a combination thereof. Network 300 may include multiple main processor cores 301 and multiple shadow processor cores 302. Main processor cores 301 may include features of main processor core 101, main processor core 201, or a combination thereof. Shadow processor cores 302 may include features of shadow processor core 102, shadow processor core 202, or a combination thereof.

Although six main processor cores 301 and six shadow processor cores 302 are shown, network 300 may include any number of main processor cores 301 and shadow processor cores 302. A quantity of main processor cores 301 in network 300 may be the same as, or different than, a quantity of shadow cores 302 in network 300. Each shadow processor core 302 may be connected to (e.g., coupled with, connected via network) at least one main processor core 301 to operate in lock step therewith during a functional safety compliance test. Shadow processor cores 302 may be physically smaller than main processor cores 301. Shadow processor cores 302 may perform some operations or computations in parallel with their associated main processor cores 301 and may assist in checking for errors.

By using a lower frequency clock, by simulating some aspects of main processor cores 301, or both, shadow processor cores 302 may incorporate area-efficient components, use an area-efficient design, or both to result in a smaller physical area than main processor cores 301. Due to the smaller physical area of shadow processor cores 302, network 300 is cost-efficient while maintaining reduced errors and adhering to safety standards (e.g., ASIL ISO 26262).

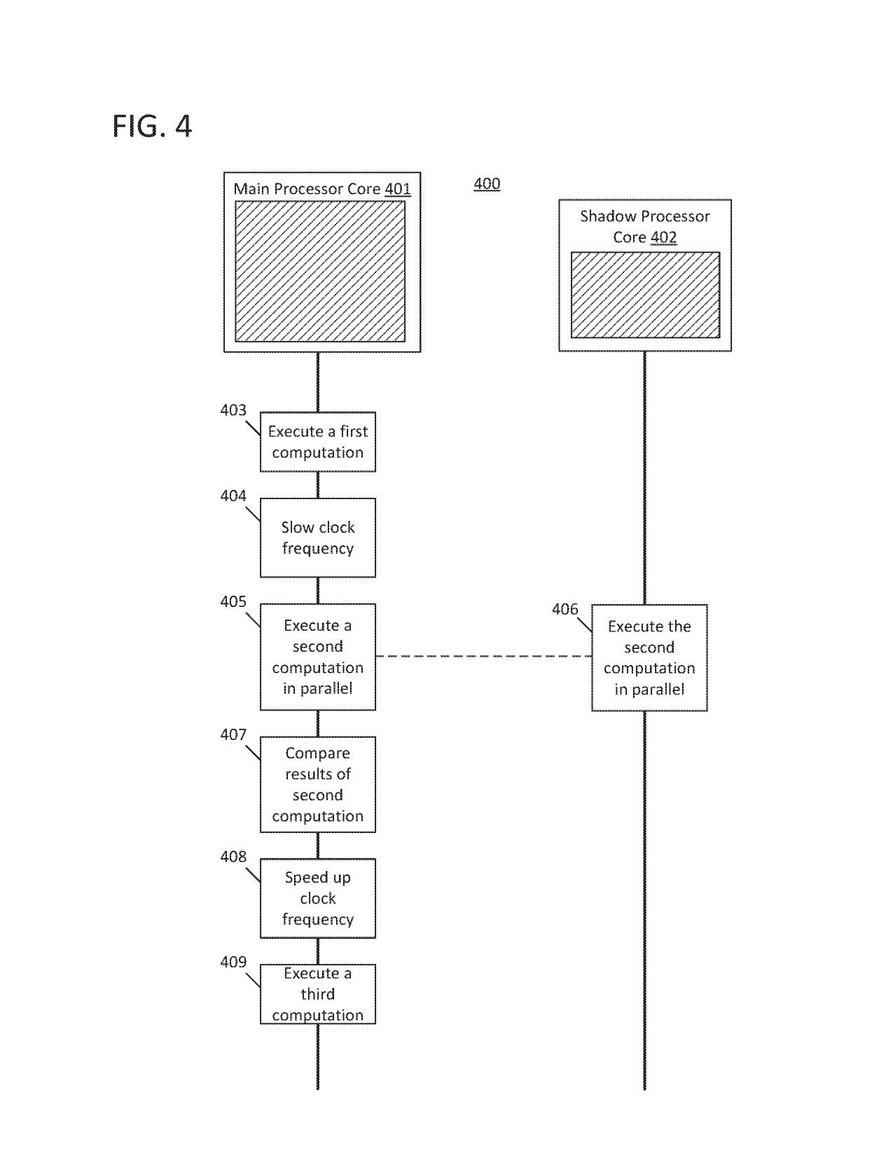

FIG. 4 illustrates a timing diagram 400 of the operations of main processor core 401 and shadow processor core 402. Main processor core 401 may correspond to main processor core 101. Shadow processor core 402 may correspond to shadow processor core 102. Some steps may be in a different order. Some steps may occur simultaneously or substantially at the same time as another step. In specific embodiments, some steps may be omitted, duplicated, or rearranged.

At 403, main processor core 401 may execute a first computation (e.g., or an operation or process). Main processor core 401 may execute the first computation at a first clock frequency. The first clock frequency may be considered a high or fast clock frequency. Shadow processor core 402 may refrain from executing the first computation. By refraining from executing the first computation, shadow processor core 402 may accordingly refrain from verifying or checking the result of the first computation.

At 404, main processor core 401 may slow its clock frequency from the first clock frequency to a second clock frequency. Slowing the clock frequency may be associated with entering a locked mode (e.g., with shadow processor core 402). The second clock frequency may be considered a low or slow clock frequency and may be associated with shadow processor core 402. Shadow processor core 402 may be unable to operate at the first clock frequency due to having a different physical layout than main processor core 401. For example, shadow processor core 402 may include components that prioritize low power or low area rather than prioritize speed.

The maximum clock frequency (e.g., Fmax) of shadow processor core 402 may be at the low or mid end of the frequency range of the main processor core 401 to enable the cores to operate at the same frequency when they are in locked mode. In locked mode, main processor core 401 may down-shift its frequency of operation to match the frequency of shadow processor core 402. By matching the frequencies, the main processor core 401 and shadow processor core 402 may match the time required for the identical operations. In typical lock step/split lock implementations comparators are used at the outputs of the main and shadow core.

At 405, main processor core 401 may execute a second computation in parallel with shadow processor core 402. At 406, shadow processor core 402 may execute the second computation in parallel with main processor core 401. Main processor core 401 and shadow processor core 402 may execute the second computation in lockstep or locked mode and at the second clock frequency.

At 407, the results of 405 and 406 may be compared. Although the comparison is shown to be done by main processor core 401, the comparison may be done at a different device. For example, in lock step/split lock implementations, comparators may be used at the outputs of main processor core 401 and shadow processor core 402. If the result of 405 (e.g., the execution of the second computation by main processor core 401) and the result of 406 (e.g., the execution of the second computation by shadow processor core 402) do not match, then an error may have occurred, and error procedures may be followed. If the result of 405 and the result of 406 match, then no error may be assumed, and the next instruction (e.g., to execute a third computation) may be followed.

At 408, main processor core 401 may speed up its clock frequency from the second clock frequency back to the first clock frequency. The second clock frequency may be associated with an error-checking mode while the first clock frequency may be associated with another mode of operation. The first computation may be the last instruction executed outside of a lock step mode and the second computation may be the first computation executed in the lock step mode.

At 409, main processor core 401 may execute a third computation (e.g., or an operation or process). Main processor core 401 may execute the third computation at the first clock frequency. The third computation may be the first instruction executed once the main processor core 401 has dropped out of lock step mode and after many computations have been conducted in lockstep mode (i.e., many computations may be executed in lock step mode before the third computation is executed). Shadow processor core 402 may refrain from executing the third computation. By refraining from executing the third computation, shadow processor core 402 may accordingly refrain from verifying or checking the result of the third computation.

Not every computation performed by main processor core 401 may require checking to adhere to safety standards. For example, the type of computation or the portion of main processor core 401 that executes the computation may not be prone to errors, or the types of errors that occur may be relatively inconsequential. In the example of timing diagram 400, the second computation is checked by shadow processor core 402, while the first and third computations are not. The network may be capable of entering and exiting lock step mode based on the computations that are being conducted or based on manual input from a higher level controller.

By refraining from checking every computation executed by main processor core 401 and by using a lower clock frequency than main processor core 401, shadow processor core 402 may incorporate area-efficient components, use an area-efficient design, or both to result in a smaller physical area than main processor core 401. Due to the smaller physical area of shadow processor core 402, the system of cores is cost-efficient while maintaining reduced errors and adhering to safety standards (e.g., ASIL ISO 26262).

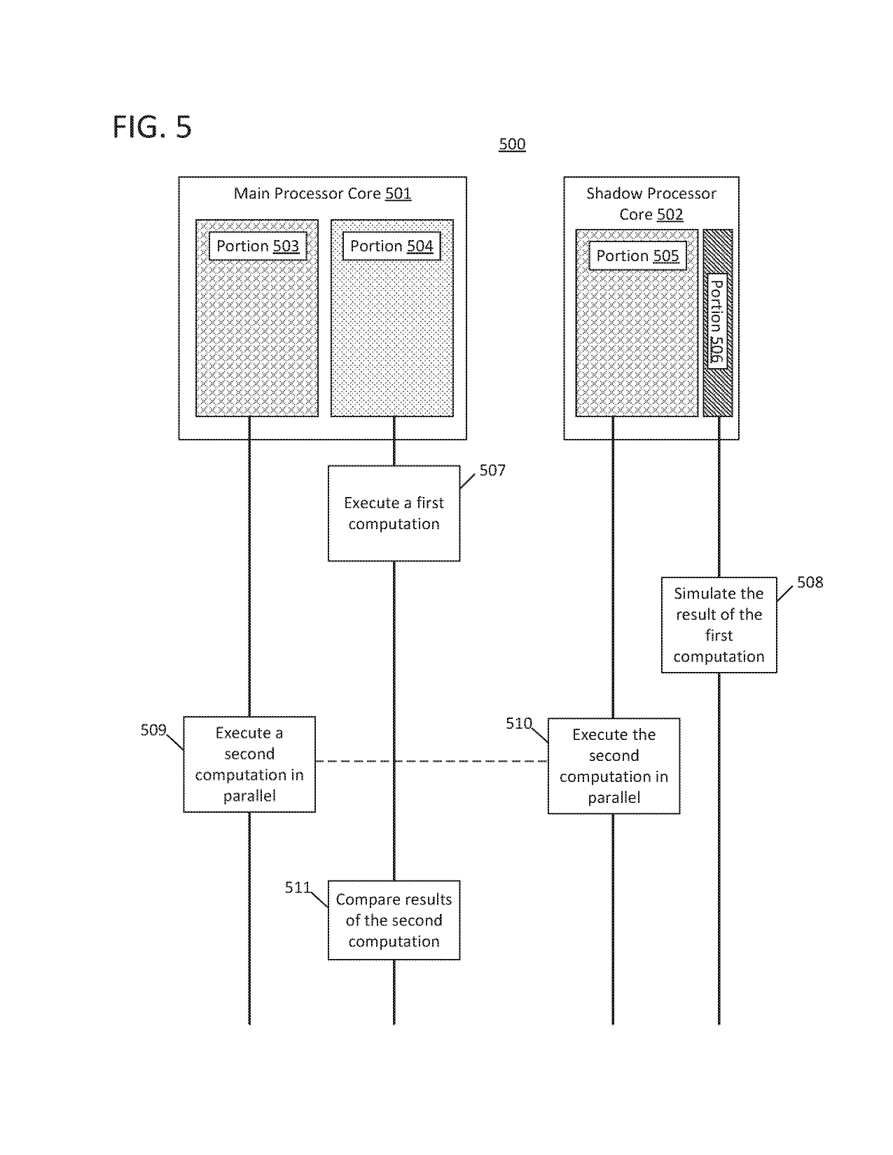

FIG. 5 illustrates a timing diagram 500 of the operations of main processor core 501 and shadow processor core 502. Main processor core 501 may correspond to main processor core 201. Shadow processor core 502 may correspond to shadow processor core 202. Some steps may be in a different order. Some steps may occur simultaneously or substantially at the same time as another step. In specific embodiments, some steps may be omitted, duplicated, or rearranged.

Prior to 507, one or more error-prone portions of main processor core 501 may be determined. For example, an iterative process or FMEDA may be performed to identify portions of main processor core 501 that are prone to errors. Portion 503 may be an error-prone portion. Portion 505 of shadow processor core 502 may have the same RTL description as (error-prone) portion 503. This duplicated RTL may allow shadow processor core 502 to verify the results of computations executed by portion 503 of main processor core 501.

Portion 506 of shadow processor core 502 may have a different RTL description than that of portion 504 of main processor core 501. This may allow shadow processor core 502 to be smaller in size than main processor core 501. Portion 506 may simulate computations executed by portion 504 rather than executing the computations.

At 507, portion 504 of main processor core 501 may execute a first computation (e.g., or an operation or process). Shadow processor core 402 may refrain from executing the first computation, as portion 504 may not be prone to errors and may be reliable. By refraining from executing the first computation, shadow processor core 502 may accordingly refrain from verifying or checking the result of the first computation.

At 508, portion 506 of shadow processor core 502 may simulate the result of the first computation as executed by portion 504 of main processor core 501 at 507. In contrast to FIG. 4, the first computation in FIG. 5 may be conducted while the devices are operating in lock step with shadow processor core 502 simulating the behavior of a less error-prone portion of main processor core 501 during the execution of the first computation at 508.

At 509, portion 503 of main processor core 501 may execute a second computation in parallel with shadow processor core 502. At 510, portion 505 of shadow processor core 502 may execute the second computation in parallel with main processor core 501. Main processor core 501 and shadow processor core 502 may execute the second computation in lockstep or locked mode. Shadow processor core 502 may execute the second computation in parallel with main processor core 501 because (error-prone) portion 503 of main processor core 501 executed the second computation, rather than (more reliable) portion 504.

At 511, the results of 509 and 510 may be compared. Although the comparison is shown to be done by portion 504 of main processor core 501, the comparison may be done at a different device, or a different portion of the device. For example, in lock step/split lock implementations, comparators may be used at the outputs of main processor core 501 and shadow processor core 502. If the result of 509 (e.g., the execution of the second computation by main processor core 501) and the result of 510 (e.g., the execution of the second computation by shadow processor core 502) do not match, then an error may have occurred, and error procedures may be followed. If the result of 509 and the result of 510 match, then no error may be assumed, and the next instruction (e.g., to execute a third or subsequent computation) may be followed.

Not every computation performed by main processor core 501 may require checking to adhere to safety standards. For example, the type of computation or the portion (e.g., portion 504) of main processor core 501 that executes the computation may not be prone to errors or the types of errors that occur may be relatively inconsequential. In the example of timing diagram 500, the second computation is checked by shadow processor core 502, while the first computation is not.

By refraining from checking every computation executed by main processor core 501 and by simulating results of main processor core 401 (e.g., via portion 506), shadow processor core 502 may incorporate area-efficient components, use an area-efficient design, or both to result in a smaller physical area than main processor core 501. Due to the smaller physical area of shadow processor core 502, the system of cores is cost-efficient while maintaining reduced errors and adhering to safety standards (e.g., ASIL ISO 26262).

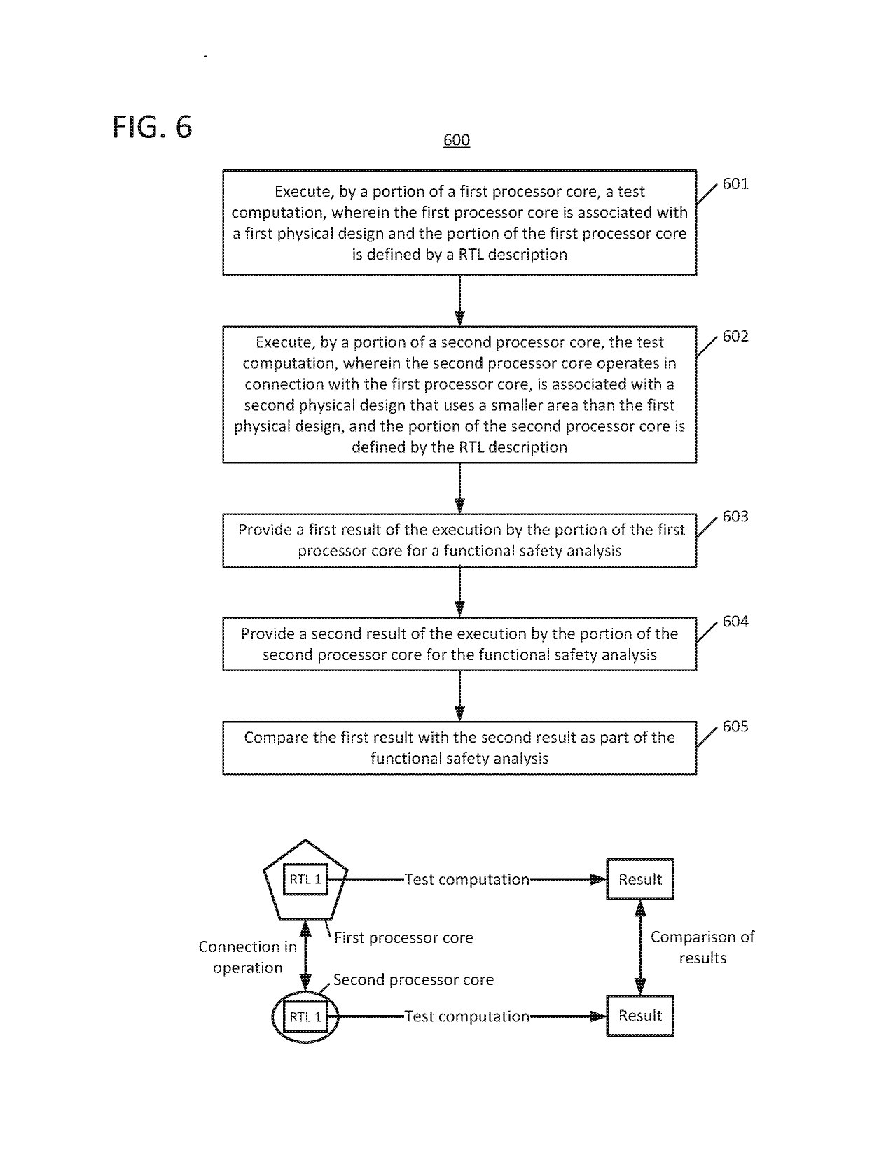

FIG. 6 illustrates method 600 in accordance with specific embodiments of the inventions disclosed herein. Method 600 may be implemented by network 100, network 200, network 300, or a combination thereof. Method 600 may include features of timing diagram 400, timing diagram 500, or a combination thereof. Some portions of method 600 may occur simultaneously or substantially at the same time as another portion. In specific embodiments, some portions of method 600 may be omitted, duplicated, or rearranged.

At 601, a portion of a first processor core may execute a test computation. The first processor core may be associated with a first physical design. The portion of the first processor core may be defined by an RTL description. The first processor core may include features of main processor core 101, main processor core 201, main processor core 301, main processor core 401, main processor core 501, or a combination thereof. The test computation may be part of the regular workload of the first processor core, but it can be considered a test computation (e.g., because a shadow core, or a second core, executes the computation at the same time).

In specific embodiments, the first physical design is entirely defined by the RTL description. In specific embodiments, the portion of the first processor core defined by the RTL description in an error-prone portion of the first processor core. A second portion of the first processor core (e.g., not defined by the RTL description, but by a different, second RTL description) may be less error-prone than the error-prone first portion of the first processor core.

At 602, a portion of a second processor core may execute the test computation. The second processor core may operate in connection with the first processor core, and the cores may operate in lockstep. The second processor core may be associated with a second physical design that uses a smaller area than the first physical design. The portion of the second processor core may be defined by the same RTL description as the portion of the first processor core. The second processor core may include features of shadow processor core 102, shadow processor core 202, shadow processor core 302, shadow processor core 402, shadow processor core 502, or a combination thereof.

In specific embodiments, the second physical design is entirely defined by the RTL description. In specific embodiments, the RTL description is implemented using higher speed physical cells in the first processor core than are used for the second physical design of the second processor core. In specific embodiments, a second portion of the second processor core is defined by a different, third RTL description. The third RTL description may be different than the RTL description of the portion of the second processor core and different than the second RTL description of the second portion of the first processor core.

At 603, a first result of the execution may be provided. The first result may correspond to the execution of the computation by the portion of the first processor core at 601. The first result may be provided for a functional safety analysis.

At 604, a second result of the execution may be provided. The second result may correspond to the execution of the computation by the portion of the second processor core at 602. The second result may be provided for a functional safety analysis.

In specific embodiments, at 605, the first result (of 603) and the second result (of 604) may be compared. The comparison may be part of the functional safety analysis. If the two results are different, then an error may be assumed. If the two results are the same, then no error may be assumed.

The second processor core may check computations of the first processor core while taking up less area than the first processor core and adhering to safety standards.

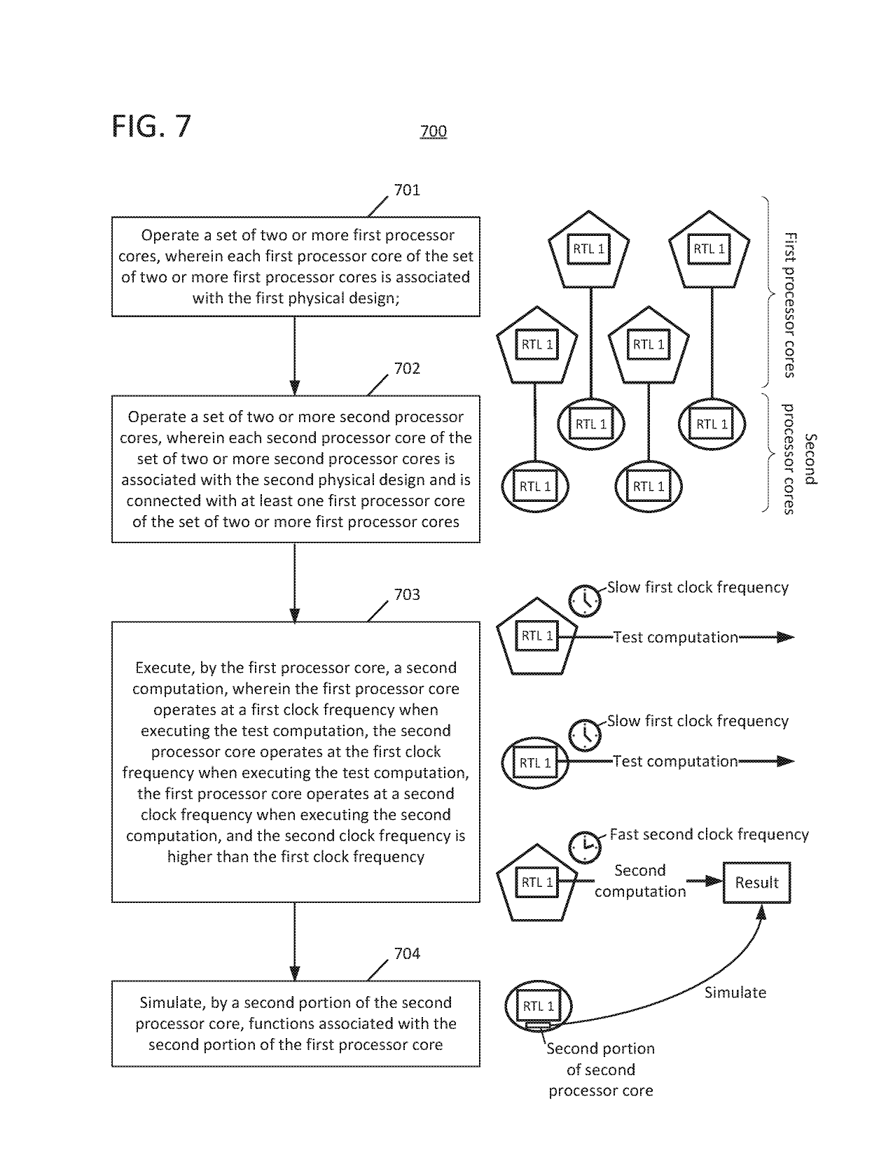

FIG. 7 illustrates method 700 in accordance with specific embodiments of the inventions disclosed herein. For example, method 700 may be a method for using a network of processor cores. Method 700 may be implemented by network 100, network 200, network 300, or a combination thereof. Method 700 may include features of timing diagram 400, timing diagram 500, or a combination thereof. Aspects of method 600 may be incorporated into method 700, for example, portions of method 700 may be a continuation of method 600. Some portions of method 700 may occur simultaneously or substantially at the same time as another portion. In specific embodiments, some portions of method 700 may be omitted, duplicated, or rearranged.

In specific embodiments, at 701, a set of (e.g., two or more) first processor cores may operate. Operating may include performing functions, computations, operations, instructions, etc. Each first processor core of the set of first processor cores may be associated with the first physical design. The first processor core may include features of the first processor core of method 600.

In specific embodiments, at 702, a set of (e.g., two or more) second processor cores may operate. Each second processor core of the set of second processor cores may be associated with the second physical design and may be connected with at least one first processor core of the set of first processor cores (e.g., operating at 701). The one or more first processor cores and the one or more second processor cores can execute a first computation in steps 701 and 702. The two sets of cores might not be operating in lock step during the execution of the first computation.

In specific embodiments, at 703, a first processor core may execute a second computation. The first processor core may operate at a different clock frequency when executing the second computation than was previously used. For example, the first processor core may operate at a first clock frequency when executing the test computation (e.g., at 601 in method 600). The second processor core may also operate at the first clock frequency when executing the test computation (e.g., at 602 in method 600). The first processor core may operate at a second clock frequency when executing the second computation. The second clock frequency may be higher (e.g., faster) than the first clock frequency.

In specific embodiments, at 704, the second portion of the second processor core may simulate functions associated with the second portion of the first processor core. For example, the second portion of the second processor core may simulate the second computation of the first processor core such that the second processor core has the result of the second computation without performing the second computation itself.

The second processor core may check computations of the first processor core while taking up less area than the first processor core and adhering to safety standards.

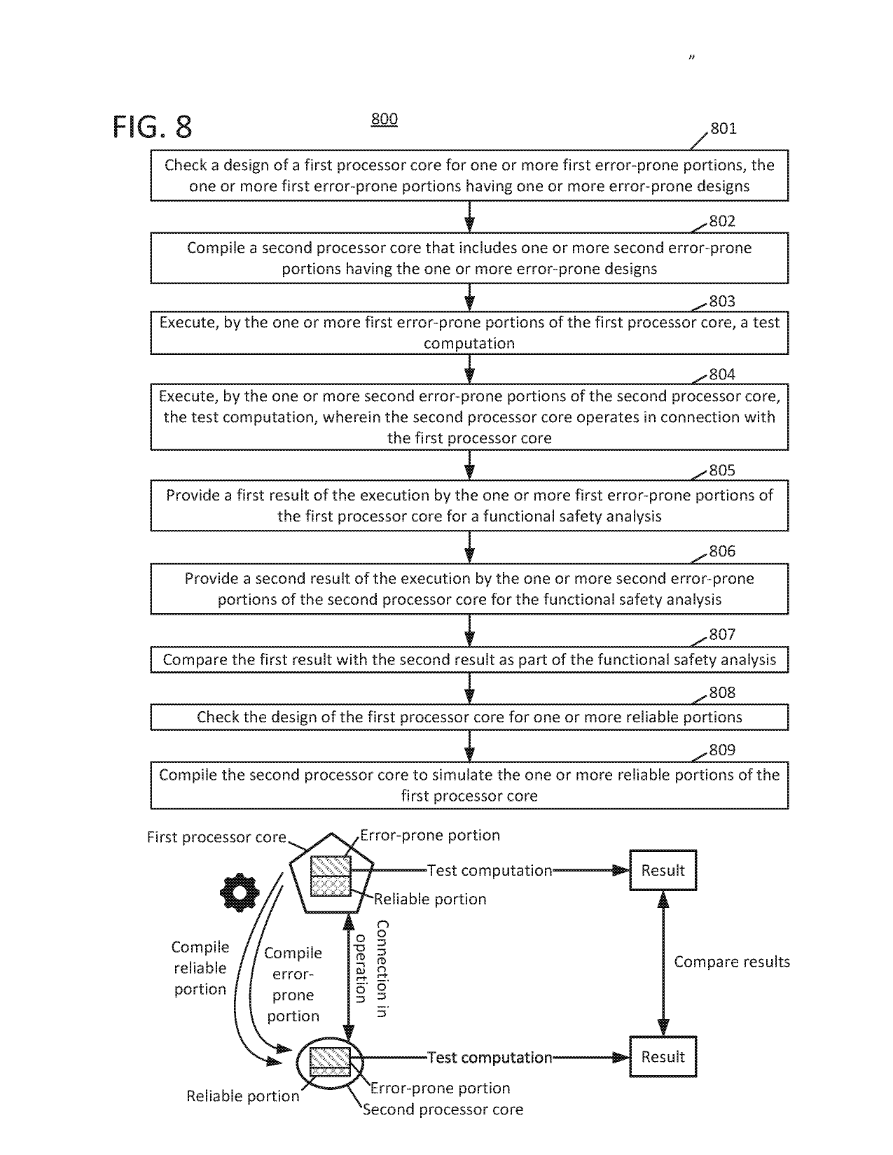

FIG. 8 illustrates method 800 in accordance with specific embodiments of the inventions disclosed herein. For example, method 800 may be a method for using a network of processor cores. Method 800 may be implemented in association with network 100, network 200, network 300, or a combination thereof. Method 800 may include features of timing diagram 400, timing diagram 500, or a combination thereof. Aspects of method 600 and of method 700 may be incorporated into method 800. Some portions of method 800 may occur simultaneously or substantially at the same time as another portion. In specific embodiments, some portions of method 800 may be omitted, duplicated, or rearranged.

At 801, a design of a first processor core may be checked for one or more first error-prone portions. The one or more first error-prone portions may have one or more error-prone designs. The design may be checked via an iterative process. The first processor core may include features of the first processor core of method 700.

At 802, a second processor core may be compiled. The second processor core may include one or more second error-prone portions having the one or more error-prone designs. The second processor core may include features of the second processor core of method 700.

At 803, the one or more first error-prone portions of the first processor core may execute a test computation.

At 804, the one or more second error-prone portions of the second processor core may execute the test computation. The second processor core may operate in connection with the first processor core.

At 805, A first result may be provided. The first result may correspond to the execution of the one or more first error-prone portions of the first processor core (e.g., execution at 803). The first result may be provided for a functional safety analysis.

At 806, a second result may be provided. The second result may correspond to the execution of the one or more second error-prone portions of the second processor core (e.g., execution at 804). The second result may be provided for a functional safety analysis.

In specific embodiments, at 807, the first result (e.g., provided at 805) and the second result (e.g., provided at 806) may be compared. The comparison may be part of a functional safety analysis.

In specific embodiments, at 808, the design of the first processor core may be checked for one or more reliable portions. Reliable portions may be less error-prone than the error-prone portions checked for at 801.

In specific embodiments, at 809, the second processor core may be compiled to simulate the one or more reliable portions of the first processor core (e.g., checked at 808).

The second processor core may check computations of the first processor core while taking up less area than the first processor core and adhering to safety standards.

A processor in accordance with this disclosure may include at least one non-transitory computer readable media. The at least one processor may comprise at least one computational node in a network of computational nodes. The media may include cache memories on the processor. The media may also include shared memories that are not associated with a unique computational node. The media may be a shared memory, may be a shared random-access memory, and may be, for example, a double data rate (DDR) dynamic random-access memory (DRAM). The shared memory may be accessed by multiple channels. The non-transitory computer readable media may store data required for the execution of any of the methods disclosed herein, the instruction data disclosed herein, and/or the operand data disclosed herein. The computer readable media may also store instructions which, when executed by the system, cause the system to execute the methods disclosed herein. The concept of executing instructions is used herein to describe the operation of a device conducting any logic or data movement operation, even if the “instructions” are specified entirely in hardware (e.g., an AND gate executes an “and” instruction). The term is not meant to impute the ability to be programmable to a device.

While the specification has been described in detail with respect to specific embodiments of the invention, it will be appreciated that those skilled in the art, upon attaining an understanding of the foregoing, may readily conceive of alterations to, variations of, and equivalents to these embodiments. Any of the method steps discussed above may be conducted by a processor operating with a computer-readable non-transitory medium storing instructions for those method steps. The computer-readable medium may be memory within a personal user device or a network accessible memory. Although examples in the disclosure were generally directed to functional safety, the same approaches could be utilized to reduce errors in any system. These and other modifications and variations to the present invention may be practiced by those skilled in the art, without departing from the scope of the present invention, which is more particularly set forth in the appended claims.

What is claimed is:

1. A network of processor cores, comprising:
a first processor core associated with a first physical design and having a portion of the first processor core defined by a register transfer level (RTL) description;
a second processor core connected with the first processor core, the second processor core being associated with a second physical design and having a portion of the second processor core defined by the RTL description, wherein the second physical design uses a smaller area than the first physical design; and
at least one non-transitory computer-readable medium storing instructions that: (i) cause the first processor core and the second processor core to execute a test computation using the portion of the first processor core and the portion of the second processor core; and (ii) cause a result of the test computation from the first processor core and a result of the test computation from the second processor core to be available for a functional safety analysis.

2. The network of processor cores of claim 1, wherein:
the first physical design is entirely defined by the RTL description;
the second physical design is entirely defined by the RTL description; and
the first physical design is implemented from the RTL description using higher speed physical cells than are used for the second physical design.

3. The network of processor cores of claim 1, wherein:
the first processor core and the second processor core operate in lockstep.

4. The network of processor cores of claim 1, further comprising:
a set of two or more first processor cores associated with the first physical design; and
a set of two or more second processor cores associated with the second physical design, wherein each second processor core of the set of two or more second processor cores operates in lockstep with at least one first processor core of the set of two or more first processor cores.

5. The network of processor cores of claim 1, further comprising:
a first computation of the first processor core, wherein, when executing the first computation, the first processor core operates at a first clock frequency;
a second computation of the first processor core, wherein, when executing the second computation, the first processor core operates at a second clock frequency that is lower than the first clock frequency; and
a third computation of the second processor core, wherein, when executing the third computation, the second processor core operates at the second clock frequency, and wherein outputs of the third computation and the second computation are compared.

6. The network of processor cores of claim 1, wherein:
the portion of the first processor core defined by the RTL description is an error-prone portion of the first processor core; and
a second portion of the first processor core is less error-prone than the error-prone portion of the first processor core and is defined by a second RTL description.

7. The network of processor cores of claim 6, further comprising:
a second portion of the second processor core, the second portion of the second processor core being defined by a third RTL description, wherein the second RTL description is different than the third RTL description.

8. The network of processor cores of claim 7, wherein:
the second portion of the second processor core simulates the second portion of the first processor core.

9. A method for conducting a functional safety analysis using a network of processor cores, comprising:
executing, by a portion of a first processor core, a test computation, wherein the first processor core is associated with a first physical design and the portion of the first processor core is defined by a register transfer level (RTL) description;
executing, using a portion of a second processor core, the test computation, wherein the second processor core operates in connection with the first processor core, is associated with a second physical design that uses a smaller area than the first physical design, and the portion of the second processor core is defined by the RTL description;
providing a first result of the execution by the portion of the first processor core for the functional safety analysis; and
providing a second result of the execution by the portion of the second processor core for the functional safety analysis.

10. The method of claim 9, wherein:
the first physical design is entirely defined by the RTL description;
the second physical design is entirely defined by the RTL description; and
the first physical design is implemented from the RTL description using higher speed physical cells than are used for the second physical design.

11. The method of claim 9, further comprising:
comparing the first result with the second result as part of the functional safety analysis.

12. The method of claim 9, wherein:
the first processor core and the second processor core operate in lockstep.

13. The method of claim 9, further comprising:
operating a set of two or more first processor cores, wherein each first processor core of the set of two or more first processor cores is associated with the first physical design; and
operating a set of two or more second processor cores, wherein each second processor core of the set of two or more second processor cores is associated with the second physical design and operates in lockstep with at least one first processor core of the set of two or more first processor cores.

14. The method of claim 9, further comprising:
executing, by the first processor core, a second computation, wherein the first processor core operates at a first clock frequency when executing the test computation, the second processor core operates at the first clock frequency when executing the test computation, the first processor core operates at a second clock frequency when executing the second computation, and the second clock frequency is higher than the first clock frequency.

15. The method of claim 9, wherein:
the portion of the first processor core defined by the RTL description is an error-prone portion of the first processor core; and
a second portion of the first processor core is less error-prone than the error-prone portion of the first processor core and is defined by a second RTL description different than the RTL description.

16. The method of claim 15, wherein:
a second portion of the second processor core is defined by a third RTL description, wherein the third RTL description is different than the second RTL description and the RTL description.

17. The method of claim 16, further comprising:
simulating, by the second portion of the second processor core, functions associated with the second portion of the first processor core.

18. A method of designing a network of processor cores for a functional safety analysis, comprising:
checking a design of a first processor core for one or more first error-prone portions, the one or more first error-prone portions having one or more error-prone designs;
compiling a second processor core that includes one or more second error-prone portions having the one or more error-prone designs and that has a different physical design than the first processor core;
executing, by the one or more first error-prone portions of the first processor core, a test computation;
executing, by the one or more second error-prone portions of the second processor core, the test computation;
providing a first result of the execution by the one or more first error-prone portions of the first processor core for a functional safety analysis; and
providing a second result of the execution by the one or more second error-prone portions of the second processor core for the functional safety analysis.

19. The method of designing the network of processor cores of claim 18, further comprising:
comparing the first result with the second result as part of the functional safety analysis.

20. The method of designing the network of processor cores of claim 18, further comprising:
checking the design of the first processor core for one or more reliable portions; and
compiling the second processor core to simulate the one or more reliable portions of the first processor core.
